(19) United States
(12) Patent Application Publication
(10) Pub. No.: US 2003/0231524 A1
(43) Pub. Date: Dec. 18, 2003

(54) Semiconductor memory device

(75) Inventor: Takashi Ohsawa, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, TOKYO (JP)

(21) Appl. No.: 10/313,018

(22) Filed: Dec. 6, 2002

(30) Foreign Application Priority Data
Jun. 18, 2002 (JP) 2002-176931

(51) Int. Cl. G11C 5/00

(52) U.S. Cl. 365/189.07

(57) ABSTRACT

A semiconductor memory device includes word lines provided along a first direction, bit lines provided along a second direction which intersects the first direction, memory cells provided at intersection points of the word lines and the bit lines, each of the memory cells including a MISFET each of which stores data as a difference of threshold voltage, reference bit lines provided along the second direction, reference cells provided at intersection points of the word lines and the reference bit lines, 2N (where N is a natural number) of the reference cells being activated by the same word line as the memory cell from which data is read out in order to generate a reference current, and a data sense circuit which reads out data from the memory cell in accordance with the reference current and a cell current flowing through the memory cell to be read.

### CROSS REFERENCE TO RELATED APPLICATION

This application claims benefit of priority under 35 U.S.C. §119 to Japanese Patent Application No. 2002-176931, filed on Jun. 18, 2002, the entire contents of which are incorporated by reference herein.

### BACKGROUND OF THE INVENTION

1. Field of the Invention

The present invention relates to a semiconductor memory device, and particularly relates to a current-read-type semiconductor memory device in which data stored in a memory cell is read by using a reference current flowing through a reference cell.

2. Description of the Related Art

The challenge imposed on a dynamic type semiconductor memory device (DRAM) is to reduce the cell size to less than 6 F² in a design rule F of less than 0.1 μm, and as a DRAM which can realize this challenge, a DRAM in which a memory cell includes an FBC (floating body transistor cell) is proposed (See, for example, Japanese Patent application No. 2001-245584, Japanese Patent Application No. 2001-328204, and Japanese Patent Application No. 2001-220461.) The entire contents of these reference are incorporated herein by reference.

Japanese Patent application No. 2001-245584 corresponds to U.S. Patent Application Publication No. 2002/0051378, Japanese Patent Application No. 2001-328204 corresponds to U.S. Patent Application Publication No. 2002/0114191, and Japanese Patent Application No. 2001-220461 corresponds to U.S. patent application Ser. No. 09/964,851. The entire contents of these reference are incorporated herein by reference.

This FBC includes a MISFET having a floating body formed on an SOI or the like, and data is stored by changing the potential of the floating body by injecting majority carriers into the floating body of the MISFET by impact ionization and by forward biasing a PN-junction between a source region or a drain region and the floating body to extract the majority carriers, and thereby changing a threshold voltage Vth of the MISFET by the body effect.

FIG. 13 is a partial arrangement plan of a semiconductor memory device having an 8-Kbit memory cell array MCA composed of FBC memory cells MC. As shown in FIG. 13, the semiconductor memory device having the memory cell array MCA composed of the FBCs adopts a double end type sense amplifier system in which sense amplifier circuits 10 are arranged on both sides of the memory cell array MCA. In this memory cell array MCA, a bit line selecting circuit 12 selects one bit line BL out of eight bit lines BL and connects it to the sense amplifier circuit 10, and one reference voltage generating circuit 14 is provided for two sense amplifier circuits 10.

The FBC is the memory cell MC capable of non-destructive read-out, a cell current is passed from a drain to a source of a MISFET, and a flowing cell current Icell is sensed. Moreover, reference cells RC0 each holding “0” data and reference cells RC1 each holding “1” data are additionally provided in one memory cell array MCA. A pair of the reference cells RC0 and RC1 are provided for one reference voltage generating circuit 14. Then, by comparing a reference current I0+I1 which is the sum of a current I0 flowing through the reference cell RC0 and a current I1 flowing through the reference cell RC1 with 2×Icell which is double the cell current, whether the threshold of the memory cell MC is in its high state or low state is sensed to thereby read data stored in the memory cell MC. Such a current-read-method of the FBC memory cell MC is described in Japanese Patent Application No. 2002-76374. Japanese Patent Application No. 2002-76374 corresponds to U.S. patent application Ser. No. 10/102,981, and the entire contents of this reference are incorporated herein by reference.

The reference cells RC0 and the reference cells RC1 are respectively connected to two reference bit lines RBL0 and RBL1 which are separated at the center of the memory cell array MCA. Moreover, a reference word line RWL0 is connected to a gate of each of the reference cells RC0, and a reference word line RWL1 is connected to a gate of each of the reference cells RC1.

No normal memory cell MC is arranged at intersection points of the reference bit lines RBL0 and RBL1 and normal word lines WL, and no memory cell MC is arranged at intersection points of the reference word lines RWL0 and RWL1 and normal bit lines BL. Furthermore, one FBC whose gate is connected to each of equalizing lines EQL is provided in each of the bit lines BL and the reference bit lines RBL0 and RBL1, and the potentials of the bit lines BL and the reference bit lines RBL0 and RBL1 are set at 0 V (GND).

In the semiconductor memory device shown in FIG. 13, variations in cell characteristics depending on the formation position of the memory cell and variations in cell characteristics due to temperature can be compensated for, as common mode noise. As shown in FIG. 13, in the case of the memory cell MC located in the 8-Kbit memory cell array MCA, the variations in cell characteristics depending on its formation position can be ignored, and the variations in cell characteristics due to temperature change can be also ignored. This is because the memory cell MC from which data is to be read and two reference cells RC0 and RC1 as a reference are formed by FBCs with the same structure, and hence if changes of device parameters such as a threshold Vth, mobility, gate oxide film thickness, channel length, and channel width of the memory cell MC which determine the cell characteristics occur in one memory cell array MCA, it is thought that these changes similarly occur to the memory cell MC and the reference cells RC0 and RC1.

In such a case, from the viewpoint of characteristics of the sense amplifier circuit 10, unless these changes exceed a certain degree, the relation between the cell current Icell and the reference current I0+I1 is considered to be almost constant. In other words, variations in cell characteristics can be compensated for, as so-called common mode noise.

In this case, it is important whether or not the assumption that the aforementioned changes of the device parameters due to process and temperature occur with the same tendency to the memory cell MC from which data is to be read and two reference cells RC0 and RC1 as the references is valid, but it is possible to think that this assumption is valid to some extent if these three FBCs exist in positions physically close to one another and surrounding environments of these FBCs are the same to a certain degree.

In the current-read-method such as described above, however, the relative distance between the memory cell MC from which data is to be read and the reference cells RC0 and RC1 become larger if the length of the bit line BL increases or the reference voltage generating circuit 14 is shared by a larger number of sense amplifier circuits 10, and hence there is a possibility that the precision of compensation for common mode noise lowers.

### SUMMARY OF THE INVENTION

In order to accomplish the aforementioned and other objects, according to one aspect of the present invention, a semiconductor memory device comprises:

a plurality of word lines provided in parallel with one another along a first direction;

a plurality of bit lines provided in parallel with one another along a second direction which intersects the first direction;

a plurality of memory cells provided at intersection points of the word lines and the bit lines, each of the memory cells including a MISFET which has a drain region connected to one of the bit lines, a source region connected to one of source lines, a gate electrode connected to one of the word lines and a floating body between the source region and the drain region, the floating body being in an electrical floating state, wherein each of the memory cells stores data as a difference of threshold voltage;

a plurality of reference bit lines provided along the second direction;

a plurality of reference cells provided at intersection points of the word lines and the reference bit lines, 2N of the reference cells being activated by the same word line as the memory cell from which data is read out in order to generate a reference current when data is read out from the memory cell, where N is a natural number; and

a data sense circuit which reads out data from the memory cell in accordance with the reference current and a cell current flowing through the memory cell to be read.

According to another aspect of the present invention, a semiconductor memory device comprises:

a plurality of word lines provided in parallel with one another along a first direction;

a plurality of bit lines provided in parallel with one another along a second direction which intersects the first direction;

a plurality of memory cells provided at intersection points of the word lines and the bit lines;

a plurality of reference bit lines provided along the second direction;

a plurality of reference cells provided at intersection points of the word lines and the reference bit lines, 2N of the reference cells being activated by the same word line as the memory cell from which data is read out in order to generate a reference current when data is read out from the memory cell, where N is a natural number; and

a data sense circuit which reads out data from the memory cell in accordance with the reference current and a cell current flowing through the memory cell to be read.

### BRIEF DESCRIPTION OF THE DRAWINGS

FIG. 1 is a partial arrangement plan of a memory cell array and its periphery in a semiconductor memory device according to a first embodiment;

FIG. 2 is a schematic sectional view explaining the structures of a memory cell and a reference cell according to the first embodiment;

FIG. 3 is a circuit diagram explaining the connection relationship among a gate electrode, a source, and a drain in the memory cell and the reference cell according to the first embodiment;

FIG. 4 is a graph for explaining a change in the threshold of the memory cell by the use of the relation between gate voltage and floating body potential;

FIG. 5 is a circuit diagram showing the configuration of a sense amplifier circuit according to the first embodiment;

FIG. 6 is a circuit diagram showing the configuration of a bit line selecting circuit according to the first embodiment;

FIG. 7 is a circuit diagram showing the configuration of a reference voltage generating circuit according to the first embodiment;

FIG. 8 is a diagram showing equivalent circuits of a first sense amplifier of the sense amplifier circuit and a second sense amplifier of the reference voltage generating circuit according to the first embodiment;

FIG. 9 is an arrangement plan of a memory cell array and its periphery in a semiconductor memory device according to a second embodiment;

FIG. 10 is an arrangement plan of a memory cell array and its periphery in a semiconductor memory device according to a third embodiment;

FIG. 11 is a circuit diagram showing the configuration of a bit line selecting circuit according to the third embodiment;

FIG. 12 is a diagram showing equivalent circuits of a first sense amplifier of a sense amplifier circuit and a second sense amplifier of a reference voltage generating circuit according to the third embodiment; and

FIG. 13 is an arrangement plan of a memory cell array and its periphery in a related semiconductor memory device.

### DETAILED DESCRIPTION OF THE INVENTION

[First Embodiment]

In the first embodiment, two reference bit lines are provided for one reference voltage generating circuit, and reference cells are arranged at intersection points of respective word lines and respective reference bit lines. The reference voltage generating circuit generates a reference current by using two reference cells provided in the same word line as a memory cell from which data is to be read, whereby the distance between the memory cell from which data is to be read and the reference cells is limited to a predetermined range. Further details will be explained below.

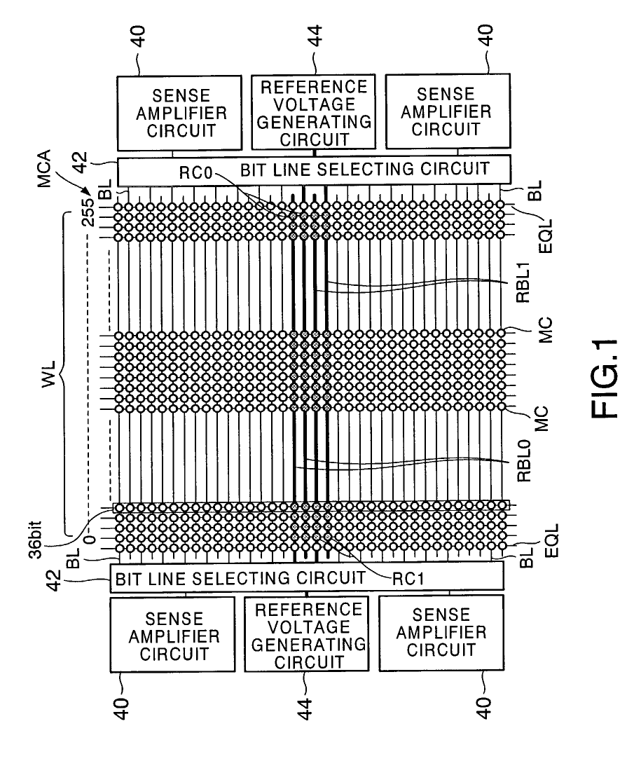

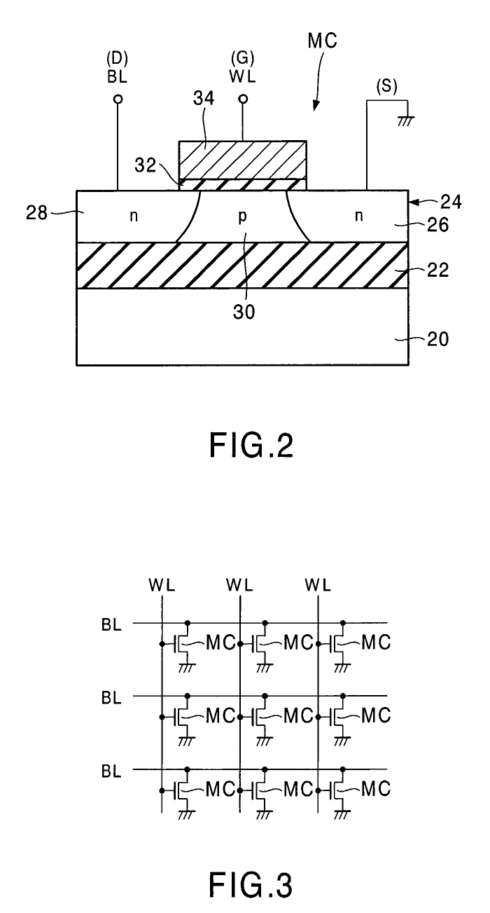

FIG. 1 is a partial arrangement plan of a semiconductor memory device according to this embodiment, FIG. 2 is a sectional view explaining the structure of the memory cell MC constituting a memory cell array according to this embodiment, and FIG. 3 is a circuit diagram showing the connection relationship in each of the memory cells MC.

As shown in FIG. 2, the memory cell MC according to this embodiment includes one MISFET having a floating channel body. More specifically, an insulating film 22 is formed on a semiconductor substrate 20, for example, formed out of silicon. In this embodiment, this insulating film 22 is formed of a silicon oxide film, for example.

A p-type semiconductor layer 24 is formed on the insulating film 22. Namely, the memory cell MC in this embodiment is formed on an SOI (silicon on insulator)substrate. An n-type source region 26 and an n-type drain region 28 are formed in the semiconductor layer 24. These source region 26 and drain region 28 are formed deep enough to reach the insulating film 22. The semiconductor layer 24 between these source region 26 and drain region 28 forms a floating body 30. An insulation region (not shown) to insulate the floating body 30 from other memory cells is formed in a channel width direction of the floating body 30. This floating body 30 is electrically insulated from other memory cells MC by the source region 26, the drain region 28, the insulating film 22, and the insulation region, and brought into a floating state. A gate electrode 34 is formed on the floating body 30 with a gate insulating film 32 therebetween.

As shown in FIG. 3, each of the memory cells MC is provided at an intersection point of a word line WL and a bit line BL, its source region 26 is connected to a ground by a common source line, its drain region 28 is connected to the bit line BL, and its gate electrode 34 is connected to the word line WL. More specifically, the drain regions 28 of the respective memory cells MC arranged in a bit line BL direction are connected in common to one bit line BL, and the gate electrodes 34 of the respective memory cells MC arranged in a word line WL direction are connected in common to one word line WL.

The memory cell MC shown in FIG. 2 and FIG. 3 dynamically stores a first data state in which the floating body 30 is set at a first potential and a second data state in which it is set at a second potential. More specifically, the first data state is written by applying a high-level voltage to the word line WL and the selected bit line BL to allow the selected memory cell MC to perform a pentode operation and thereby causing impact ionization near its drain junction to generate majority carriers (holes in the case of an n-channel) and holding them in the floating body 30. This is, for example, data “1”. The second data state is written by applying a high-level voltage to the word line WL to raise the potential of the floating body 30 by capacitive coupling, setting the bit line BL at a low-level voltage, and passing a forward bias current through a junction between the floating body 30 and the drain region 28 of the selected memory cell MC to emit majority carriers in the floating body 30 to the drain region 28. This is, for example, data “0”.

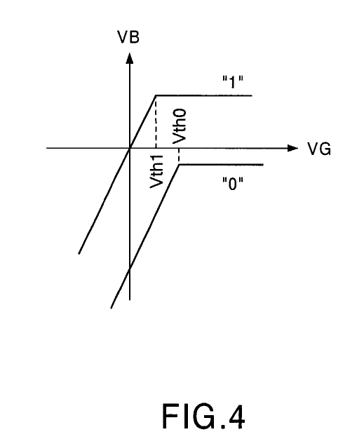

Whether the memory cell MC holds the data “1” or the data “0” is shown by a difference in MISFET gate threshold. That is, the threshold voltage of the MISFET is changed in accordance with the number of the majority carriers accumulated in the floating body 30. The relation between a floating body potential VB and a gate voltage VG of the memory cell MC holding the data “1” and the relation between the floating body potential VB and the gate voltage VG of the memory cell MC holding the data “0” are shown by a graph in FIG. 4.

As shown in FIG. 4, as the result of a body bias by the floating body potential VB, a threshold voltage Vth1 of the memory cell MC holding the data “1” becomes lower than a threshold voltage Vth0 of the memory cell MC holding the data “0”. Therefore, data read from the memory cell MC can be determined by sensing a difference in cell current due to a difference in threshold voltage.

As shown in FIG. 1, in this embodiment, an 8-Kbit memory cell array MCA includes the memory cells MC. More specifically, 256 word lines WL are provided in parallel with one another along a column direction, and 32 bit lines BL are provided in parallel with one another along a row direction which intersects the column direction. In this embodiment, especially, the word lines WL and the bit lines BL intersect at right angles.

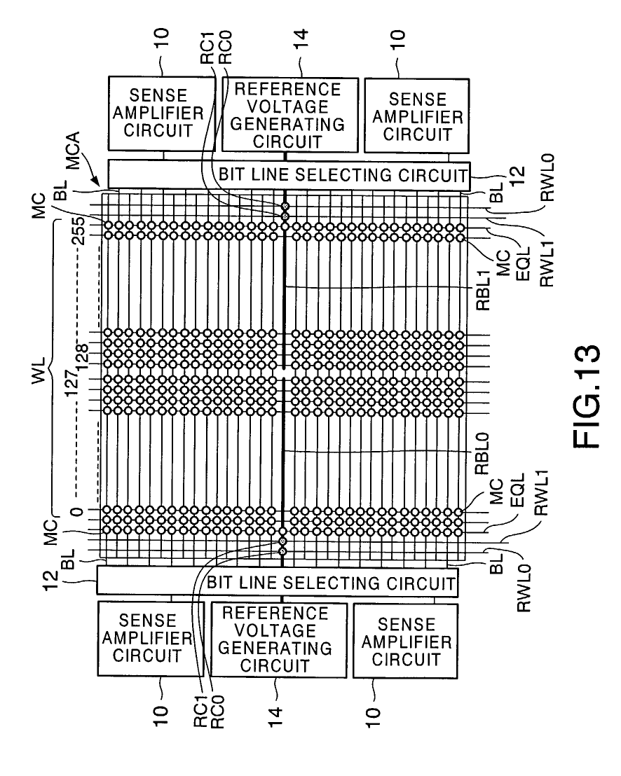

Further, in this embodiment, four reference bit lines RBL0 and RBL1 are provided in parallel along a bit line direction. Especially in this embodiment, the reference bit lines RBL0 and RBL1 are provided in the central portion of the memory cell array MCA. Hence, 16 bit lines BL are provided on the upper side of the reference bit lines RBL0 and RBL1 in FIG. 1, and similarly 16 bit lines BL are provided on the lower side of the reference bit lines RBL0 and RBL1 in FIG. 1. In other words, with respect to the reference bit lines RBL0 and RBL1, the number of the bit lines BL provided on one side of a word line direction and the number of the bit lines BL provided on the other side of the word line direction are the same. Furthermore, in this embodiment, unlike a related memory cell array MCA shown in FIG. 13, the reference bit lines RBL0 and RBL1 are not divided into two parts at the center, and likewise with the normal bit lines BL, they are each formed by one line across the entire memory cell array MCA.

Two reference bit lines RBL0 are provided with reference cells RC0, in which the “0” data is to be held, at their intersection points with respective word lines WL. Namely, 256 reference cells RC0 are connected to one reference bit line RBL0. Moreover, two reference bit lines RBL1 are provided with reference cells RC1, in which the “1” data is to be held, at their intersection points with respective word lines WL. Namely, 256 reference cells RC1 are connected to one reference bit line RBL1. The structures of these reference cells RC0 and RC1 are the same as that of the memory cell MC. Moreover, the connection relationship among a gate electrode, a source, and a drain is the same as that of the memory cell MC shown in FIG. 3.

Further, at both end of the memory cell array MCA in the bit line direction, one equalizing line EQL is provided along the word lines WL, respectively. MISFETs each having the same structure and the same connection relationship as the memory cell MC are provided at intersection points of the equalizing line EQL and the bit lines BL and intersection points of the equalizing line EQL and the reference bit lines RBL0 and RBL1, and their gates are connected to the equalizing line EQL. Before data is read from the memory cell MC, the bit line BL is set at a ground (0 V) via this equalizing line EQL.

On both sides of the memory cell array MCA thus configured in the bit line direction, sense amplifier circuits 40 are placed. Namely, the memory cell array MCA according to this embodiment adopts a double end type sense amplifier system. Therefore, bit line selecting circuits 42 are also placed on both sides of the memory cell array MCA in the bit line direction.

The bit lines BL are alternately connected to the bit line selecting circuits 42 on both sides, and the reference bit lines RBL0 and RBL1 are also alternately connected thereto. By this bit line selecting circuit 42, one out of eight bit lines BL on the upper side of the reference bit lines RBL0 and RBL1 in FIG. 1 is selected and connected to the sense amplifier circuit 40 on the upper side of FIG. 1, and one out of eight bit lines BL on the lower side of the reference bit lines RBL0 and RBL1 in FIG. 1 is selected and connected to the sense amplifier circuit 40 on the lower side of FIG. 1.

One reference voltage generating circuit 44 is provided for two sense amplifier circuits 40 on one side. When data in the memory cell MC is read, one reference bit line RBL0 and one reference bit line RBL1 are both connected to this reference voltage generating circuit 44. A data sense circuit according to this embodiment includes these reference voltage generating circuit 44 and sense amplifier circuits 40.

In the semiconductor memory device thus configured, a data read sequence with respect to one memory cell MC is performed, in outline, as follows. First, one word line WL is selected and set at a predetermined high-level voltage VDD. Simultaneously with this, one bit line BL is selected by the bit line selecting circuit 42 and connected to the sense amplifier circuit 40. Moreover, one reference bit line RBL0 and one reference bit line RBL1 are connected to the reference voltage generating circuit 44 by the bit line selecting circuit 42.

Then, a cell current Icell is sent to the memory cell MC from which data is to be read via the selected bit line BL. The sense amplifier circuit 40 acquires the Icell flowing through this memory cell MC. The amount of the cell current Icell flowing through the memory cell MC differs according to whether the memory cell MC holds the data “0” or the data “1”.

Similarly, the cell current is also sent to the reference bit line RBL0 and the reference bit line RBL1 from the reference voltage generating circuit 44. Concerning the reference cells RC0 and RC1, since the reference cell RC0 and the reference cell RC1 which are connected to the same word line as the memory cell MC from which data is to be read are activated, a current I0 flows through the reference cell RC0, and a current I1 flows through the reference cell RC1. The reference voltage generating circuit 44 then acquires a reference current I0+I1 which is the sum of these currents.

The reference voltage generating circuit 44 generates a reference voltage VREF based on this reference current I0+I1 and supplies it to the sense amplifier circuits 40. The sense amplifier circuit 40 generates a data voltage VSN based on the cell current Icell and the reference voltage VREF and compares this read voltage VSN and the reference voltage VREF to thereby sense data held in the memory cell MC.

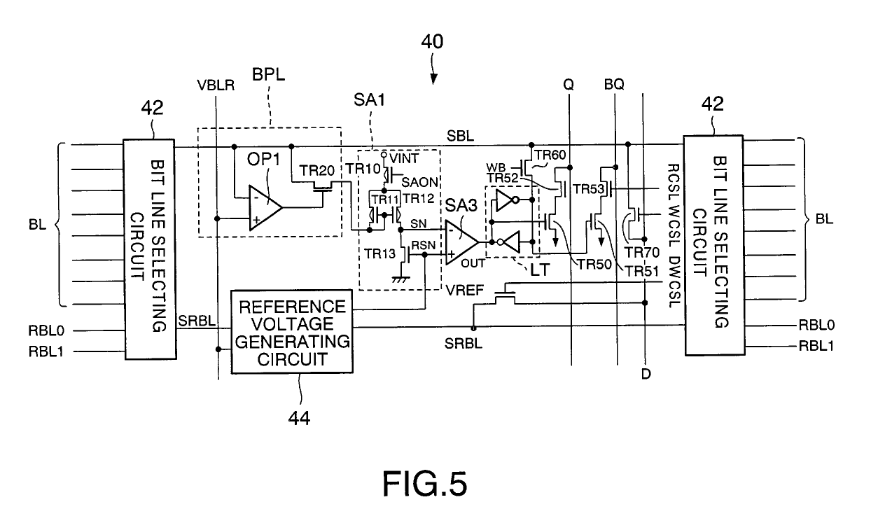

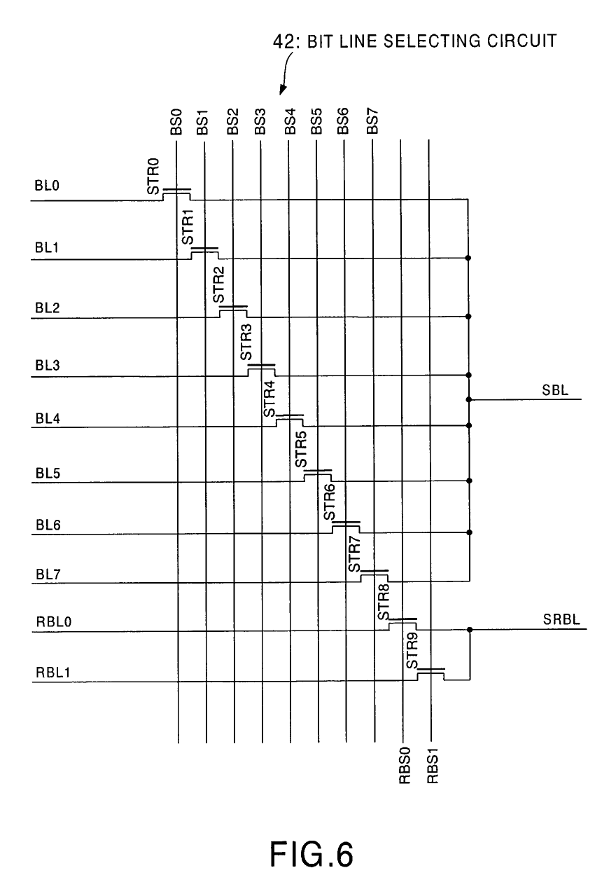

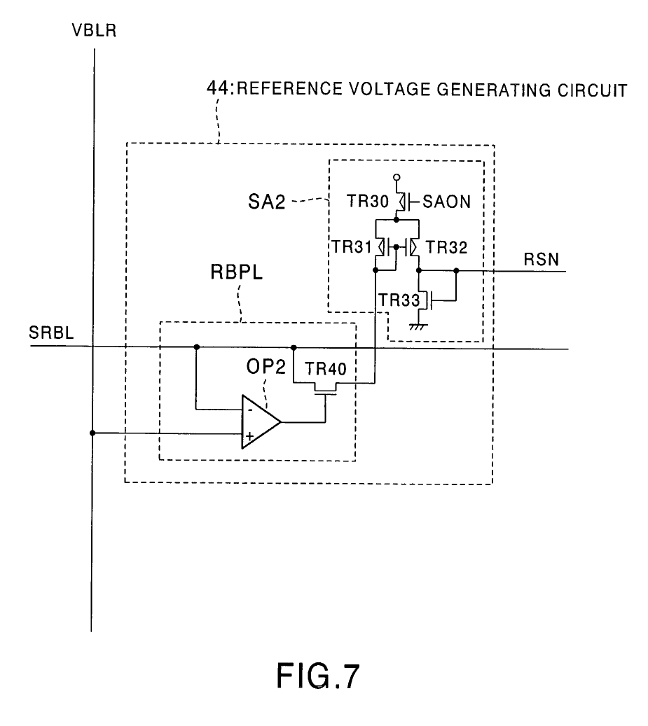

Next, the circuit configurations of the sense amplifier circuit 40, the bit line selecting circuit 42, and the reference voltage generating circuit 44 will be explained in detail. FIG. 5 is a diagram showing the circuit configuration of the sense amplifier circuit 40 according to this embodiment, FIG. 6 is a diagram showing the circuit configuration of the bit line selecting circuit 42 according to this embodiment, and FIG. 7 is a diagram showing the circuit configuration of the reference voltage generating circuit 44 according to this embodiment.

As shown in FIG. 6, eight bit lines BL0 to BL7 and two reference bit lines RBL0 and RBL1 are connected to the bit line selecting circuit 42. Incidentally, if FIG. 6 is brought into correspondence with FIG. 1, another eight bit lines BL8 to BL15 are connected on the lower side of the two bit lines RBL0 and RBL1 in FIG. 6, and the same configuration is given as that of the upper side of FIG. 6, but it is omitted in FIG. 6.

The eight bit lines BL0 to BL7 are respectively connected to input terminal sides of selection transistors STR0 to STR7, and output terminal sides of these selection transistors STR0 to STR7 are connected in common to a selection bit line SBL. Bit line selection signal lines BS0 to BS7 are respectively connected to control terminals of the selection transistors STR0 to STR7. When one bit line is selected, any one of these bit line selection signal lines BS0 to BS7 is activated and goes high to allow one bit line BL to be connected to the selection bit line SBL.

The reference bit lines RBL0 and RBL1 are respectively connected to input terminal sides of selection transistors STR8 and STR9, and output terminal sides of these selection transistors STR8 and STR9 are connected in common to a selection reference bit line SRBL. Reference bit line selection signal lines RBS0 to RBS1 are respectively connected to control terminals of the selection transistors STR8 to STR9. When data in the memory cell MC is read, both of the reference bit line selection signal lines RBS0 to RBS1 are activated and go high, and thereby both the selection transistors STR8 and STR9 are turned on. Consequently, the reference bit line RBL0 and the reference bit line RBL1 are short-circuited. However, when data is written into the reference cells RC0 and RC1, for example, when the reference cells RC0 and RC1 are refreshed, either of the reference bit line selection signal line RBS0 or RBS1 is activated and goes high. Namely, when the “0” data is written into the reference cell RC0, the selection transistor STR8 is turned on, and when the “1” data is written into the reference cell RC1, the selection transistor STR9 is turned on.

As shown in FIG. 5, the sense amplifier circuit 40 includes a first sense amplifier SA1. This first sense amplifier SA1 is configured, including p-type MISFETs TR10 to TR12 and an n-type MISFET TR13. An input terminal of the MISFET TR10 is connected to a high-level voltage terminal VINT, and an output terminal thereof is connected to input terminals of the MISFET TR11 and the MISFET TR12. Control terminals of these MISFETs TR11 and TR12 are connected to each other to constitute a current mirror circuit. The mirror ratio of the MISFET TR11 to the MISFET TR12 in this current mirror circuit is 1:2. Namely, a current, which is double the current flowing through the MISFET TR11, tries to flow through the MISFET TR12. Moreover, the control terminal and an output terminal of the MISFET TR11 are connected to the selection bit line SBL via an n-type MISFET provided in a bit line potential limiting circuit BPL.

An output terminal of the MISFET TR12 is connected to an input terminal of the MISFET TR13, and an output terminal of the MISFET TR13 is connected to the ground. A node between these MISFET TR12 and MISFET TR13 is a sense node SN.

At the time of a read sequence to read data from the memory cell MC, a signal SAON goes low, and the MISFET TR10 is turned on. As a result, a current flows from the high-level voltage terminal VINT to the selection bit line SBL via the MISFET TR11 and a MISFET TR20. This current is the cell current Icell. The amount of the cell current Icell flowing to the selection bit line SBL differs according to data held by the selected memory cell MC. Here, the cell current flowing when the selected memory cell MC holds the “0” data is represented by 10, and the cell current flowing when the selected memory cell MC holds the “1” data is represented by I1.

The bit line potential limiting circuit BPL is a circuit for limiting a rise in the potential of the bit line BL. Namely, the bit line potential limiting circuit BPL with the aforementioned MISFET TR20 and an operational amplifier OP1 constitutes a negative feedback control circuit. A voltage VBLR is inputted to a noninverting input terminal of the operational amplifier OP1. In this embodiment, this voltage VBLR is 200 mV. An inverting input terminal of the operational amplifier OP1 is connected to the selection bit line SBL. An output terminal of the operational amplifier OP1 is connected to a control terminal of the MISFET TR20. Therefore, when the potential of the selection bit line SBL exceeds the voltage VBLR, that is, when the potential of the bit line BL exceeds the voltage VBLR, an output of the operational amplifier OP1 goes low, and the n-type MISFET TR20 is turned off. Consequently, it can be avoided that the voltage of the bit line BL becomes equal to or higher than the voltage VBLR.

A rise in the potential of the bit line BL is avoided as described above for the following reason. At the time of data write, a high-level voltage (power supply voltage VDD, for example) is applied to the word line WL, and the high-level voltage (power supply voltage VDD, for example) is also applied to the bit line BL, whereby the memory cell MC performs a pentode operation. Supposing that the power supply voltage VDD is also applied to word line WL at the time of data read, it is possible that the potential of the bit line BL rises to the power supply voltage VDD unless a sufficient cell current flows through the memory cell MC. If the potential of the bit line BL rises to the power supply voltage VDD, the same conditions as those in a write mode are produced in the read operation. Thus, in this embodiment, the voltage VBLR is set at a value lower than the power supply voltage VDD. For example, the power supply voltage VDD is set at 1V to 1.5V and the voltage VBLR=200 mV. Such setting eliminates the possibility that the memory cell MC performs the pentode operation at the time of data read, and consequently it becomes possible not to fulfill conditions of the pentode operation.

As shown in FIG. 7, a selection reference bit line potential limiting circuit RBPL for limiting a rise in the potential of the selection reference bit line SRBL is provided in the reference voltage generating circuit 44. The reason why the selection reference bit line potential limiting circuit RBPL is provided is the same as above. This selection reference bit line potential limiting circuit RBPL includes an operational amplifier OP2 and an n-type MISFET TR40, and the connection relationship between them is the same as that in the aforementioned bit line potential limiting circuit BPL.

Moreover, the reference voltage generating circuit 44 includes a second sense amplifier SA2. This second sense amplifier SA2 is configured, including p-type MISFETs TR30 to TR32 and an n-type MISFET TR33, and the connection relationship among them is the same as that in the aforementioned sense amplifier SA1. However, the mirror ratio of a current mirror circuit composed of the MISFET TR31 and the MISFET TR32 is 1:1. Namely, a current whose amount is the same as the amount of a current flowing through the MISFET TR31 tries to flow through the MISFET TR32. A portion between the MISFET TR32 and the MISFET TR33 constitutes a reference node RSN, and a control terminal of the MISFET TR33 is connected to the reference node RSN.

Further, as can be seen from FIG. 7 and FIG. 5, the reference node RSN is connected to a control terminal of the MISFET TR13 of the first sense amplifier SA1. Hence, a current mirror circuit includes the MISFET TR33 and the MISFET TR13. The mirror ratio of this current mirror circuit is 1:1.

As shown in FIG. 7, in the read sequence, the signal SAON goes low, and the MISFET TR30 is turned on. Therefore, a current flows from the high-level voltage terminal VINT to the selection reference bit line SRBL via the MISFET TR31 and the MISFET TR40. This is a reference current. This reference current has an amount which is the sum of the amount of the current I0 flowing through the reference cell RC0 holding the data I0 and the amount of the current I1 flowing through the reference cell RC1 holding the data “1”.

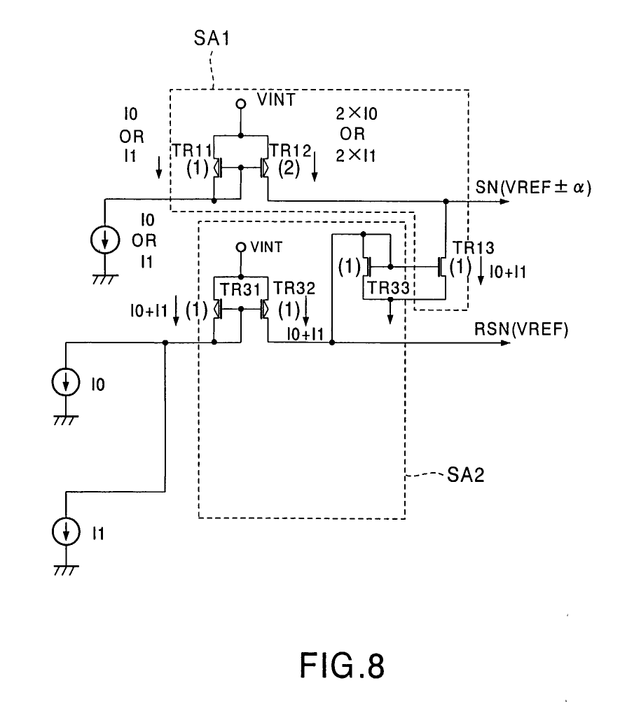

FIG. 8 is a diagram showing equivalent circuits of the first sense amplifier SA1 and the second sense amplifier SA2 in the data read sequence. Numerical values in parentheses by the side of MISFETs represent mirror ratios of the current mirror circuits.

As can be seen from FIG. 8 and FIG. 5, the cell current Icell (I0 or I1) flowing through the memory cell MC from which data is read is doubled by the current mirror circuit composed of the MISFET TR11 and the MISFET TR12, and a current of 2×Icell tries to flow through the MISFET TR12.

On the other hand, the reference current I0+I1 is multiplied by one by the current mirror circuit composed of the MISFET TR31 and the MISFET TR32. The voltage of the reference node RSN at this time is the reference voltage VREF. Moreover, the reference current I0+I1 is multiplied by one by the current mirror circuit composed of the MISFET TR33 and MISFET TR13, and then the reference current I0+I1 tries to flow through the MISFET TR13. By a collision of the reference current I0+I1 which tries to flow through the MISFET TR13 and the double cell current 2×Icell which tries to flow through the MISFET TR12, the voltage (data voltage) of the sense node SN is fixed.

More specifically, when the 2×Icell is smaller than the reference current I0+I1, the force which tries to turn on the MISFET TR13 and pass the current I0+I1 is stronger than the force which tries to turn on the MISFET TR12 and pass the current 2×Icell. Hence, the data voltage of the sense node SN is lower than the reference voltage VREF, and it is VREF−α.

On the other hand, when the 2×Icell is larger than the reference current I0+I1, the force which tries to turn on the MISFET TR12 and pass the current 2×Icell is stronger than the force which tries to turn on the MISFET TR13 and pass the current I0+I1. Hence, the data voltage of the sense node SN is higher than the reference voltage VREF, and it is VREF+α.

As can be seen from above, the polarity of the difference between the voltage of the sense node SN and the voltage of the reference node RNS differs according to data. This voltage difference is sensed by a third sense amplifier SA3 as shown in FIG. 5. In this embodiment, the third sense amplifier SA3 includes an operational amplifier and outputs a low-level or high-level sense output OUT depending on whether the potential of the sense node SN is higher or lower than that of the reference node RSN. This sense output OUT is latched by a latch circuit LT.

The sense output OUT latched by the latch circuit LT turns on either of an n-type MISFET TR50 or an n-type MISFET TR51 according to whether it is high or low. A read column selection signal RCSL is inputted to control terminals of an n-type MISFET TR52 and an n-type MISFET TR53, and the read column selection signal RCSL is high in the sense amplifier circuit 40 having the selected memory cell MC, whereby these MISFETs TR52 and TR53 are on. Moreover, in the read sequence, data read lines Q and QB are both precharged high. Therefore, either the data read line Q or the data read line BQ changes to a low level according to whether the sense output OUT is high or low. Consequently, it becomes possible to output the read data to the outside.

In a refresh sequence, a write-back signal WB goes high, and an n-type MISFET TR60 is turned on. Thereby, the sense output OUT latched by the latch circuit LT is outputted to the selection reference bit line SBL, and data is written again to the selected memory cell MC.

When data is written into the memory cell MC, a write column selection signal WCSL goes high, and an n-type MISFET TR70 is turned on. Then, a data write line D is set high or low according to data to be written, and outputted to the selection bit line SBL. For example, in this embodiment, when the data “1” is written, the data write line D goes high, and holes which are majority carriers are accumulated in a floating body of the memory cell MC selected by the word line WL driven high. On the other hand, when the data “0” is written, the data write line D goes low, and the accumulated holes are extracted from the floating body of the memory cell MC selected by the word line WL driven high. Consequently, the data can be written into the selected memory cell MC.

As stated above, according to the semiconductor memory device according to this embodiment, as shown in FIG. 1, the distance between the memory cell MC from which data is to be read and the reference cells RC0 and RC1 used in this read sequence can be limited to a predetermined range. Namely, in an example in FIG. 1, the distance between the memory cell MC from which data is to be read and the reference cells RC0 or RC1 to be used can be limited to a distance corresponding to 18 memory cells MC at the maximum. Hence, variations in cell characteristics due to a manufacturing process and variations in cell characteristics due to operating temperature conditions can be made to have the same tendency. This makes it possible to precisely compensate for these variations as common mode noise.

Moreover, when attention is focused on one memory cell array MCA, in the memory cell array MCA in FIG. 13, it is necessary to activate four reference word lines RWL0 and RWL1 in addition to one normal word line WL in the read sequence, but in the memory cell array MCA in FIG. 1, it is required to activate only one normal word line. Consequently, a reduction in power consumption in the read sequence can be realized.

[Second Embodiment]

Although one reference voltage generating circuit 44 is shared by two sense amplifier circuits 40 in the aforementioned first embodiment, it is not necessarily required to share it. In the second embodiment, one reference voltage generating circuit 44 is used by one sense amplifier circuit 40.

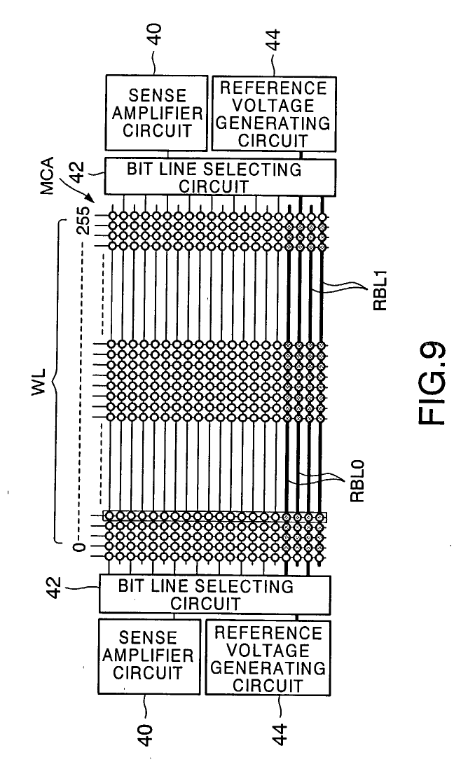

FIG. 9 shows a partial arrangement plan of a semiconductor memory device according to the second embodiment. As shown in FIG. 9, in the second embodiment, one reference voltage generating circuit 44 is provided for one sense amplifier circuit 40. In an example in FIG. 9, 4-Kbit memory cell array MCA is constituted. Points other than this one are the same as those in the aforementioned first embodiment.

As can be seen from above, it is possible to use one reference voltage generating circuit 44 by X (X is a natural number) sense amplifier circuits 40.

[Third Embodiment]

In the aforementioned embodiments, four reference cells RC0 and RC1 are provided for one word line WL. Namely, one reference voltage generating circuit 44 is designed to acquire the reference current I0+I1 by using one reference cell RC0 holding the “0” data and one reference cell RC1 holding the “1” data. However, the number of reference cells provided for one reference voltage generating circuit 44 is not limited to two, and it has only to be 2N (N is a natural number). In this case, the number of the reference bit lines RBL0 and RBL1 in total for one reference voltage generating circuit 44 needs to be 2N.

Thus, the third embodiment is designed in such a manner that four reference cells RC0 and RC1 are provided for one reference voltage generating circuit 44, two reference cells RC0 hold the “0” data, and that two reference cells RC1 hold the “1” data.

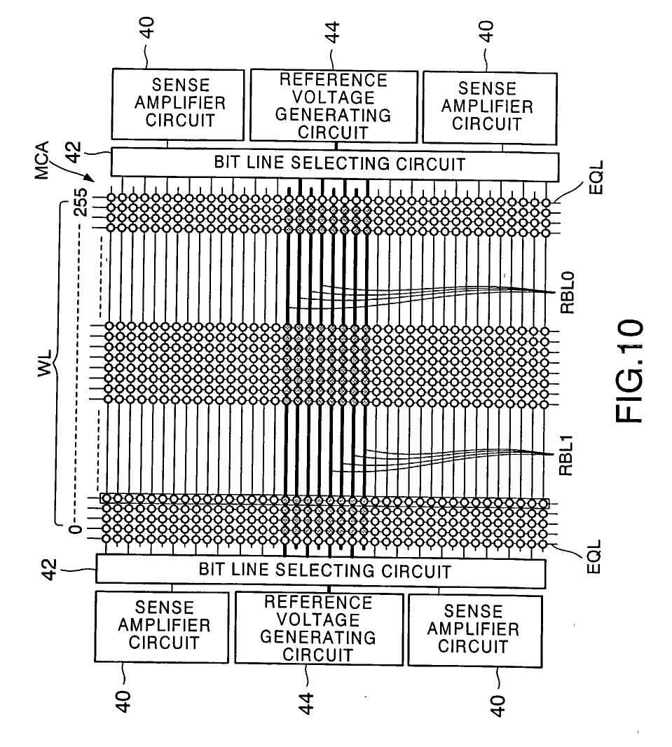

FIG. 10 is a partial arrangement plan of such a semiconductor memory device. As shown in FIG. 10, the memory cell array MCA according to this embodiment is provided with eight reference bit lines RBL0 and RBL1 along the bit lines BL in its central portion. In this embodiment, four reference bit lines RBL0 are arranged on the upper side of the word line direction, and four reference bit lines RBL1 are arranged on the lower side of the word line direction. Moreover, the reference bit lines RBL0 and RBL1 are alternately connected to the bit line selecting circuit 42 on the left side of FIG. 10 and the bit line selecting circuit 42 on the right side thereof.

The reference cells RC0 holding the “0” data are respectively provided at intersection points of the word lines WL and the reference bit lines RBL0. The reference cells RC1 holding the “1” data are respectively provided at intersection points of the word lines WL and the reference bit lines RBL1.

Similarly to FIG. 3 of the aforementioned first embodiment, also in this embodiment, a gate electrode in each of the reference cells RC0 and RC1 and the memory cells MC is connected to the word line WL, a source is connected to the ground via a common source line, and a drain is connected to the bit line BL.

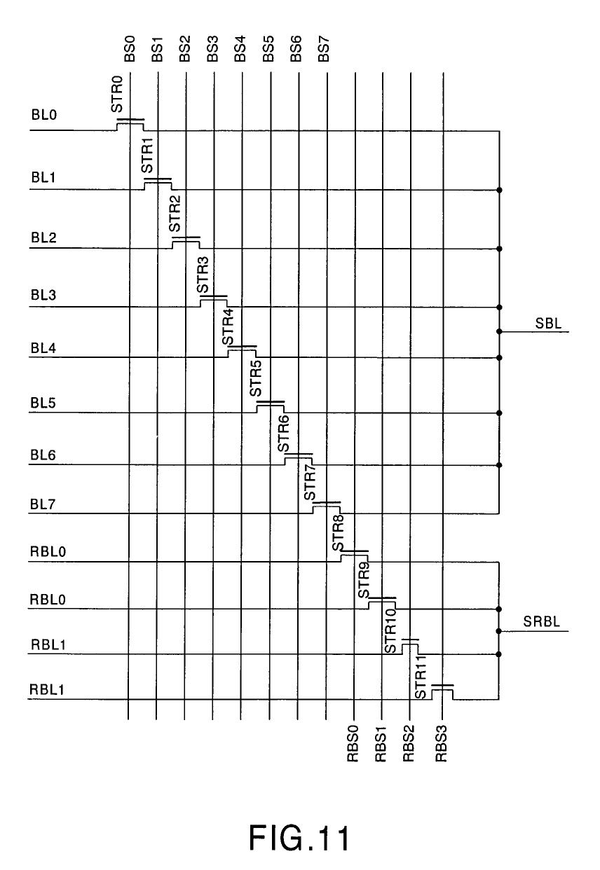

FIG. 11 shows a circuit diagram of the bit line selecting circuit 42 according to this embodiment. As shown in FIG. 11, two reference bit lines RBL0 and two reference bit lines RBL1 are connected to the bit line selecting circuit 42. Selection transistors STR8 to STR11 are provided in these total four reference bit lines RBL0 and RBL1. Reference bit line selection signal lines RBS0 to RBS3 are respectively connected to control terminals of these selection transistors STR8 to STR11.

When data in the memory cell MC is read, all of the reference bit line selection signal lines RBS0 to RBS3 are activated and go high, and thereby all of the selection transistors STR8 to STR11 are turned on. Consequently, two reference bit lines RBL0 and two reference bit lines RBL1 are short-circuited, and connected to the selection reference bit line SRBL However, when data is written into the reference cells RC0 and RC1, for example, when the reference cells RC0 and RC1 are refreshed, any two of the reference bit line selection signal line RBS0 to RBS3 are activated and go high, and thereby any two of the selection transistors STR8 to STR11 are turned on, and the selection transistors other than these two are turned off.

Except for these points, the semiconductor memory device according to this embodiment has the same configuration as the semiconductor memory device in the aforementioned first embodiment.

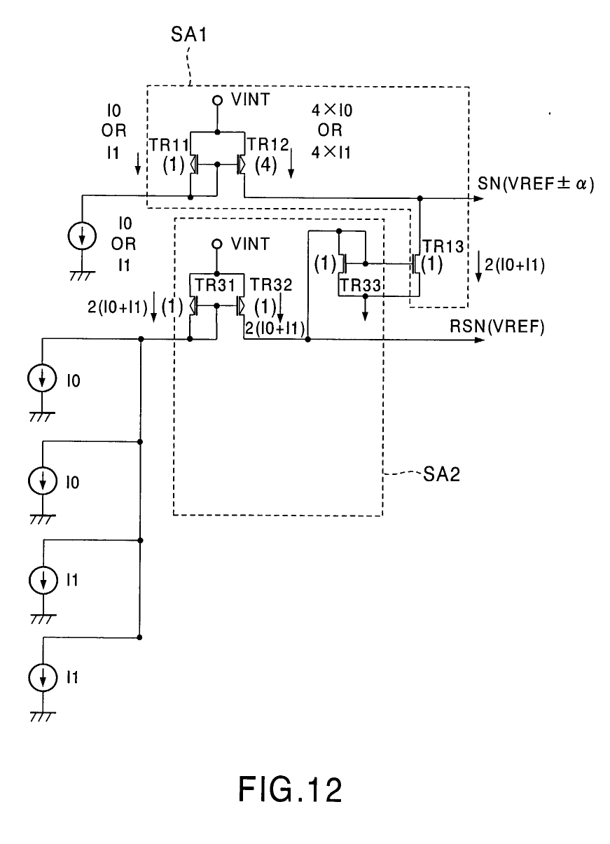

FIG. 12 is a diagram showing equivalent circuits of the first sense amplifier SA1 and the second sense amplifier SA2 in this embodiment and corresponds to FIG. 8 described above. In FIG. 12, unlike FIG. 8, a reference current flowing through the MISFET TR31 from its input terminal to its output terminal is 2×(I0+I1). This is because two reference cells RC0 and two reference cells RC1 which are selected by the word line WL are connected to the output terminal of the MISFET TR31.

Correspondingly to the above, the mirror ratio of the current mirror circuit composed of the MISFET TR11 and the MISFET TR12 becomes 1:4. As a result, a current of 4×I0 or 4×I1 tries to flow from an input terminal to an output terminal of the MISFET TR12. The voltage of the sense node SN changes to VREF−α or VREF+α according to whether the current which tries to flow through the MISFET TR12 is 4×I0 or 4×I1.

From the above description, it is found that when the number of reference cells is 2N, the reference current is multiplied by P by the current mirror circuit composed of the MISFET TR31 and the MISFET TR32, and the read cell current is multiplied by Q by the current mirror circuit composed of the MISFET TR11 and the MISFET TR12, such setting as satisfies the relation of P/Q=1/(2N) is required, where P and Q are respectively any given positive numbers.

Therefore, for example, in an example in FIG. 8 in the first embodiment, it is also possible to multiply the reference current I0+I1 by ½ by the current mirror circuit composed of the MISFET TR31 and MISFET TR32, multiply the read cell current by one by the current mirror circuit composed of the MISFET TR11 and the MISFET TR12, and compare both of them.

It should be noted that the present invention is not limited to the aforementioned embodiments, and various modifications may be made therein. For example, the present invention is not limited to a semiconductor memory device formed using FBCs as memory cells, and can be applied to any current-read-type semiconductor memory device in which data stored in a memory cell is read based on a reference current flowing through a reference cell and a cell current flowing through a memory cell from which the data is to be read.

What is claimed is:

1. A semiconductor memory device comprising:
a plurality of word lines provided in parallel with one another along a first direction;
a plurality of bit lines provided in parallel with one another along a second direction which intersects the first direction;
a plurality of memory cells provided at intersection points of the word lines and the bit lines, each of the memory cells including a MISFET which has a drain region connected to one of the bit lines, a source region connected to one of source lines, a gate electrode connected to one of the word lines and a floating body between the source region and the drain region, the floating body being in an electrical floating state, wherein each of the memory cells stores data as a difference of threshold voltage;
a plurality of reference bit lines provided along the second direction;
a plurality of reference cells provided at intersection points of the word lines and the reference bit lines, 2N of the reference cells being activated by the same word line as the memory cell from which data is read out in order to generate a reference current when data is read out from the memory cell, where N is a natural number; and
a data sense circuit which reads out data from the memory cell in accordance with the reference current and a cell current flowing through the memory cell to be read.

2. The semiconductor memory device as set forth in claim 1, wherein the structure of the reference cells is the same as that of the memory cells.

3. The semiconductor memory device as set forth in claim 1, wherein, with respect to the reference bit lines, the number of the bit lines provided on one side of the first direction is the same as the number of the bit lines provided on the other side of the first direction.

4. The semiconductor memory device as set forth in claim 1, wherein, in 2N of the reference cells activated by one word line, N of the reference cells is for storing “0” data and the remaining N reference cells is for storing “1” data.

5. The semiconductor memory device as set forth in claim 1, further comprising:
a reference voltage generating circuit which generates a reference voltage in accordance with the reference current generated by the 2N reference cells which are activated; and
a sense amplifier circuit which generates a data voltage in accordance with the reference voltage and the cell current in order to read out data from the memory cell by comparing the data voltage with the reference voltage.

6. The semiconductor memory device as set forth in claim 5, wherein 2N of the reference bit lines are provided for one reference voltage generating circuit.

7. The semiconductor memory device as set forth in claim 5, wherein one sense amplifier circuit is provided for one reference voltage generating circuit.

8. The semiconductor memory device as set forth in claim 5, wherein a plurality of sense amplifier circuits are provided for one reference voltage generating circuit.

9. The semiconductor memory device as set forth in claim 6, wherein one sense amplifier circuit is provided for one reference voltage generating circuit.

10. The semiconductor memory device as set forth in claim 6, wherein a plurality of sense amplifier circuits are provided for one reference voltage generating circuit.

11. The semiconductor memory device as set forth in claim 5, wherein the structure of the reference cells is the same as that of the memory cells.

12. The semiconductor memory device as set forth in claim 11, wherein, in 2N of the reference cells activated by one word line, N of the reference cells is for storing “0” data and the remaining N reference cells is for storing “1” data.

13. The semiconductor memory device as set forth in claim 12, wherein the data sense circuit multiplies the reference current by P, multiplies the cell current by Q, and compares the reference current multiplied by P with the cell current multiplied by Q in order to read out data from the memory cell, where P and Q are any given positive numbers.

14. The semiconductor memory device as set forth in claim 13, wherein P/Q is ½N.

15. The semiconductor memory device as set forth in claim 1, wherein the threshold voltage of the MISFET is changed in accordance with the number of majority carriers accumulated in the floating body.

16. A semiconductor memory device comprising:
a plurality of word lines provided in parallel with one another along a first direction;
a plurality of bit lines provided in parallel with one another along a second direction which intersects the first direction;
a plurality of memory cells provided at intersection points of the word lines and the bit lines;
a plurality of reference bit lines provided along the second direction;
a plurality of reference cells provided at intersection points of the word lines and the reference bit lines, 2N of the reference cells being activated by the same word line as the memory cell from which data is read out in order to generate a reference current when data is read out from the memory cell, where N is a natural number; and
a data sense circuit which reads out data from the memory cell in accordance with the reference current and a cell current flowing through the memory cell to be read.
